(19) United States
(12) Patent Application Publication
(10) Pub. No.: US 2016/0049488 A1
(43) Pub. Date: Feb. 18, 2016

(54) SEMICONDUCTOR GATE WITH WIDE TOP OR BOTTOM

(71) Applicant: GLOBALFOUNDRIES Inc., Grand Cayman (KY)

(72) Inventors: Yan Ping SHEN, Saratoga Springs, NY (US); Haiting WANG, Clifton Park, NY (US); Min-hwa CHI, Malta, NY (US); Yong Meng LEE, Mechanicville, NY (US)

(73) Assignee: GLOBALFOUNDRIES Inc., Grand Cayman (KY)

(21) Appl. No.: 14/458,941

(22) Filed: Aug. 13, 2014

(51) Int. Cl. H01L 29/423; H01L 21/3213; H01L 21/8234; H01L 27/105; H01L 27/088; H01L 29/66; H01L 27/11

(52) U.S. Cl. CPC H01L 29/42376; H01L 29/66545; H01L 29/6656; H01L 29/6653; H01L 21/32133; H01L 27/1104; H01L 27/1052; H01L 27/088; H01L 21/823437

(57) ABSTRACT

A semiconductor structure with wide-bottom and/or wide-top gates includes a semiconductor substrate, a source region(s), a drain region(s) associated with the source region(s), and a gate(s) associated with the source region(s) and the drain region(s) having a top portion and a bottom portion. One of the top portion and the bottom portion of the gate(s) is wider than the other of the top portion and bottom portion. The wide-bottom gate is created using a dummy wide-bottom gate etched from a layer of dummy gate material, creating spacers for the dummy gate, removing the dummy gate material and filling the opening created with conductive material. For the wide-top gate, first and second spacers are included, and instead of removing all the dummy gate material, only a portion is removed, exposing the first spacers. The exposed portion of the first spacers may either be completely or partially removed (e.g., tapered), in order to increase the area of the top portion of the gate to be filled.

### BACKGROUND OF THE INVENTION

1. Technical Field

The present invention generally relates to semiconductor devices having gates and the fabrication thereof. More particularly, the present invention relates to widening the top or bottom of semiconductor gates as compared to the other of the gate top or bottom.

2. Background Information

Modern fabrication of semiconductor devices, for example, planar CMOS transistors or three-dimensional FinFETs, may include a process that is known as “replacement metal gate” (RMG) or “gate last” flow on bulk substrate or silicon-on-insulator (SOI). This involves building a dummy gate as a placeholder for the final or replacement gate. However, the RMG process has some shortcomings, particularly as device sizes continue to shrink. For example, some processes (e.g., lithography) used to set the critical dimension (CD) of the dummy gate and/or the replacement gate can result in a channel of a different length than intended. For example, logic devices perform better with a smaller channel length but larger top CD for low gate resistance, as compared to SRAM memory devices using larger channel length for reducing mismatch. One attempt at a solution has been to remove part of or “chamfer” the gate sidewalls at the top. However, chamfering adds expensive process steps.

Therefore, a need exists for cost-effective, improved gates and the fabrication thereof.

### SUMMARY OF THE INVENTION

The shortcomings of the prior art are overcome and additional advantages are provided through the provision, in one aspect, of a method of fabricating a semiconductor structure. The method includes providing a starting semiconductor structure, the structure including a semiconductor substrate and a layer of dummy gate material over the substrate. The method further includes etching the layer of dummy gate material to create at least one dummy gate such that a subsequent replacement gate has one of a top portion and a bottom portion thereof that is wider than the other of the top portion and the bottom portion.

In accordance with another aspect, a semiconductor structure is provided. The structure includes a semiconductor substrate, at least one source region, at least one drain region associated with the at least one source region, and at least one gate associated with the at least one source region and the at least one drain region and having a top portion and a bottom portion. One of the top portion and the bottom portion of the gate is wider than the other of the top portion and the bottom portion of the gate.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a starting semiconductor structure, including a semiconductor substrate and a layer of dummy gate material over the substrate, in accordance with one or more aspects of the present invention.

FIG. 2 depicts the structure of FIG. 1 after creating dummy gate structures having a bottom portion of the gate structures being wider than the top portion of the gate structure, providing a tapered side profile, in accordance with one or more aspects of the present invention.

FIG. 3 depicts the structure of FIG. 2 after replacing the dummy gate structures with final gate structures, including creation of first spacers immediately adjacent the gate structures, creation of second spacers immediately adjacent the first spacers, removal of the dummy gate material to create a gate opening, and filling the gate opening with conducting material, in accordance with one or more aspects of the present invention.

FIG. 4 depicts the structure of FIG. 2 (vertical gate sidewall version) after creation of first spacers immediately adjacent the gate structures, creation of second spacers immediately adjacent the first spacers, and removal of a top portion of the dummy gate structures, exposing the first spacers, in accordance with one or more aspects of the present invention.

FIG. 5 depicts the structure of FIG. 4 after removal of a top portion of the first spacers above a top surface of the remaining bottom portion of the dummy gate structures, in accordance with one or more aspects of the present invention.

FIG. 6 depicts the structure of FIG. 5 after removal of the bottom portion of the dummy gates, exposing the bottom portion of the first spacers, in accordance with one or more aspects of the present invention.

FIG. 7 depicts the structure of FIG. 6 after filling the gates with conductive material, the gates having a top portion that is wider than the bottom portion of the gate, in accordance with one or more aspects of the present invention.

FIG. 8 depicts the structure of FIG. 4 after removing a portion of the first spacers above a top surface of the remaining bottom portion of the dummy gate structures, resulting in the top portion of the first spacers having a tapered profile, in accordance with one or more aspects of the present invention.

FIG. 9 depicts the structure of FIG. 7 after filling the gates with conductive material, the gates having a top portion that is wider than the bottom portion of the gate, in accordance with one or more aspects of the present invention.

FIG. 10 depicts the structure of FIG. 8 after filling the gates with conductive material, the gates having a top portion that is wider than the bottom portion of the gate, the top portions of the inner spacers having a tapered profile, in accordance with one or more aspects of the present invention.

FIG. 11 depicts one example of a simplified, non-planar version of the structure of FIG. 2, including a semiconductor substrate, one or more raised semiconductor structures coupled to the substrate, and dummy gate structures having a bottom portion being wider than the top portion of the gate structure, providing a tapered side profile, in accordance with one or more aspects of the present invention

FIG. 12 depicts one example of the non-planar structure of FIG. 11 after replacing the dummy gate structures with final gate structures, including creation of first spacers immediately adjacent the gate structures, creation of second spacers immediately adjacent the first spacers, removal of the dummy gate material to create a gate opening, and filling the gate opening with conducting material, in accordance with one or more aspects of the present invention.

FIG. 13 depicts one example of the non-planar structure of FIG. 11 (vertical gate sidewall version), a non-planar version of FIG. 9, after creation of first spacers immediately adjacent the gate structures, creation of second spacers immediately adjacent the first spacers, removal of the dummy gate material to create a gate opening, removal of a top portion of the first spacers, and filling the gate opening with conducting material, in accordance with one or more aspects of the present invention.

FIG. 14 depicts one example of the non-planar structure of FIG. 11 (vertical gate sidewall version), a non-planar version of FIG. 10, after creation of first spacers immediately adjacent the gate structures, creation of second spacers immediately adjacent the first spacers, removal of the dummy gate material to create a gate opening, removal of a tapered portion of a top part of the first spacers, and filling the gate opening with conducting material, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

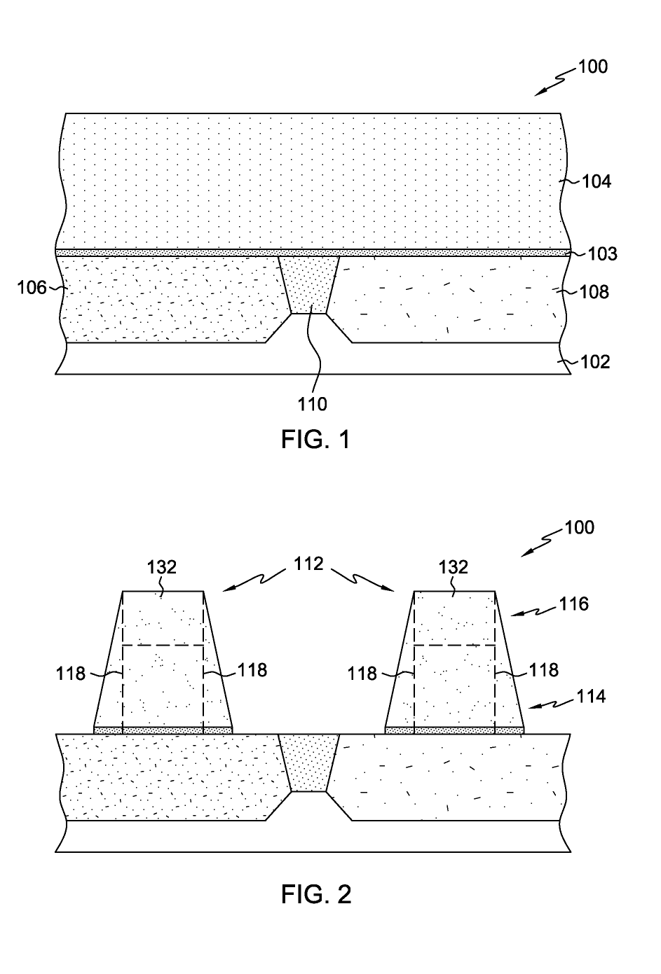

FIG. 1 is a cross-sectional view of one example of a starting semiconductor structure 100, in accordance with one or more aspects of the present invention. The structure includes a semiconductor substrate 102, a thin (e.g., about 10 nm to about 100 nm) layer 103 of a protective material, for example, an oxide and/or a nitride (e.g., silicon oxide, silicon nitride or a combination thereof), and a layer of dummy gate material 104 over the substrate. In this example, the starting structure is planar, but the present invention is also applicable to non-planar semiconductor structures, for example, semiconductor substrates with raised structures (e.g., “fins”) formed. The structure also includes, for example, a first well 106 of n-type or p-type, and a second well 108 of the opposite type, the wells being separated by isolation material 110.

The starting structure may be conventionally fabricated, for example, using known processes and techniques. However, it will be understood that the fabrication of the starting structure forms no part of the present invention. Further, although only a portion is shown for simplicity, it will be understood that, in practice, many such structures are typically included on the same bulk substrate or SOI, for example.

In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features, such as wells 106 and 108. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof an alloy semiconductor including GaAsP, AlInAs, GaInAs, GaInP, or GaInAsP or combinations thereof.

FIG. 2 depicts the structure of FIG. 1 after creating dummy gate structures 112 having a bottom portion 114 being wider than a top portion 116 of the gate structure, hereafter referred to as a “wide-bottom gate,” which in this example takes the form of a tapered side profile, in accordance with one or more aspects of the present invention. Although a vertical side profile is typically preferred, where the tapered side profile is desired, formation thereof may be accomplished by, for example, plasma-based etching of the layer 104 of dummy gate material. Alternatively, a wide-top gate, explained in detail below, may be fabricated using the vertical dummy gate side profile (as indicated by dashed lines 118). The dummy gate structures may be created, for example, by dry (or plasma) etching the dummy gate material. In one example, the dummy gate material may include polycrystalline silicon, and may be patterned by lithographic means, including the use of a lithographic blocking material, for example, photoresist, plasma (anisotropic) etching, and removal thereof after patterning.

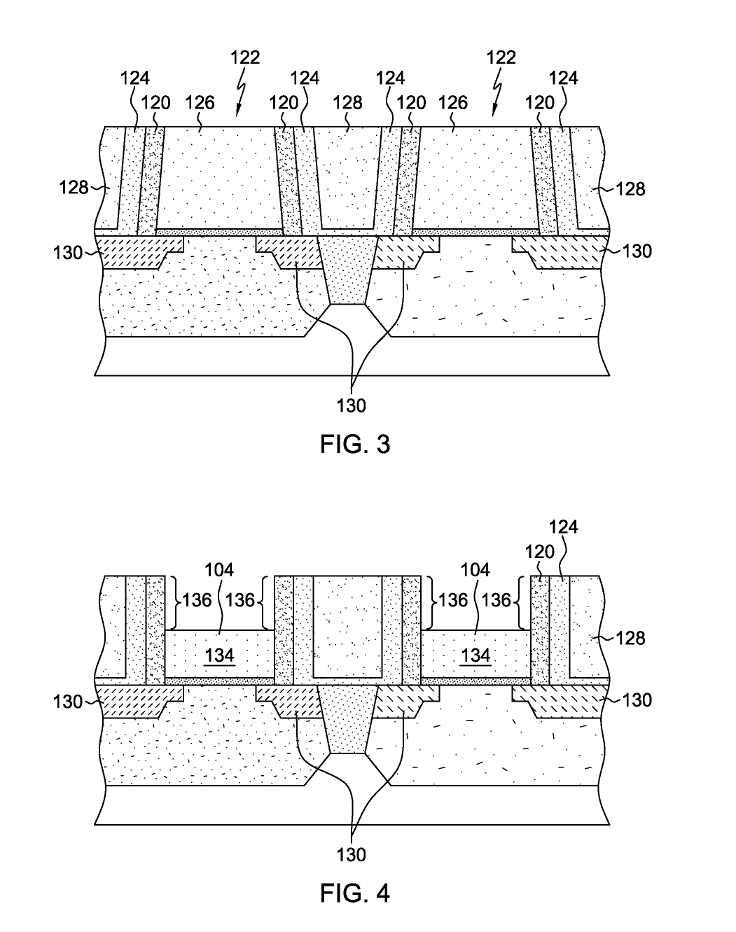

FIG. 3 depicts the structure of FIG. 2 after replacing the dummy gate structures with final gate structures, including creation of first spacers 120 immediately adjacent replacement gate structures 122 (in their dummy form), creation of second spacers 124 immediately adjacent the first spacers, removal of the dummy gate material to create a gate opening, and filling the gate opening with, for example, a gate dielectric and conducting gate electrode material (collectively, 126), in accordance with one or more aspects of the present invention. Also shown in FIG. 3 is isolation material 128 between adjacent gate structures, as well as source/drain regions 130.

The spacers may be created using, for example, a conformal deposition, followed by an etch back and/or a planarizing process. In one example, the first spacers 120 may include a nitride, e.g., carbon-doped silicon nitride (SiCN), which may be etched using, for example, a fluorine-containing plasma etch chemistry, and the planarizing may be accomplished, for example, using a chemical-mechanical polish (CMP). Second spacers 124 may include, for example, a low-k carbon-doped oxide or oxy-nitride (e.g., SiOC or SiOCN). As used herein, “low-k” refers to a dielectric constant below 7.8 (that of silicon nitride). Isolation material 128 may include, for example, a silicon oxide (e.g., carbon-doped flowable oxide), and may be created, for example, with a blanket fill, followed by planarization (e.g., chemical-mechanical polishing).

The example of FIG. 3 assumes that wide-top gates (discussed in detail below) are co-fabricated with the wide-bottom gates. Two sets of spacers are needed for the wide-top gates, since the spacer pair closest to the gate will be partially removed in order to widen the top critical dimension, without substantially removing or etching the second spacer 124 and the isolation material 128. If the wide-bottom gate was not co-fabricated, then the two sets of spacers would not be needed; a single set of spacers would suffice, since there is no partial spacer removal for the wide-bottom gate.

FIG. 4 depicts the structure of FIG. 2 (the vertical sidewall option) after creation of first spacers immediately adjacent the gate structures, creation of second spacers immediately adjacent the first spacers, and removal of a top portion (132, FIG. 2) of the dummy gate structures, exposing first spacers 120, in accordance with one or more aspects of the present invention.

Creation of the spacers, isolation material and source/drain regions may be accomplished, for example, as described above with respect to FIG. 4. Removal of the top portion 132 of the dummy gate structures, leaving bottom portion 134, may be accomplished, for example, using a dry etch, e.g., reactive ion etching (RIE).

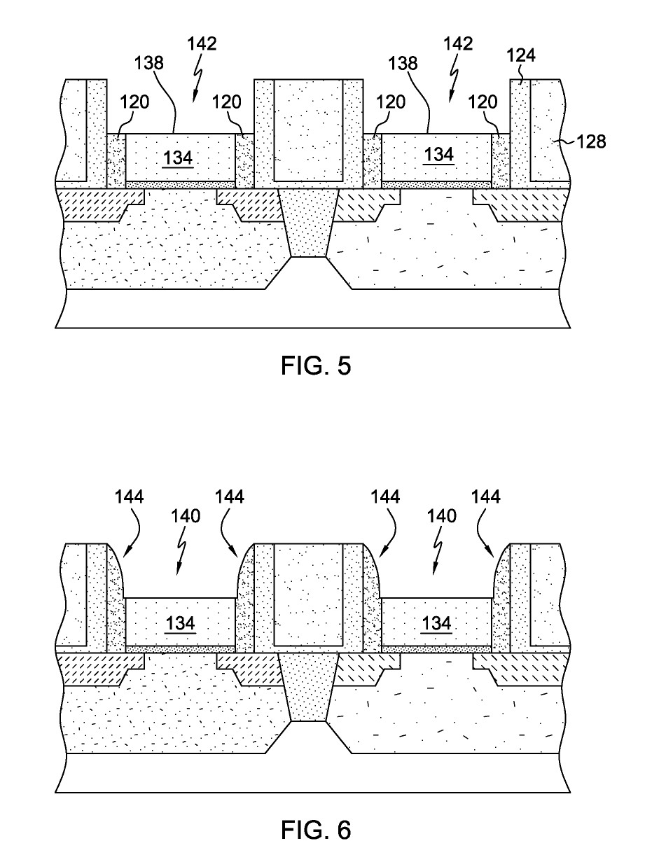

FIG. 5 depicts the structure of FIG. 4 after removal of a top portion (136, FIG. 4) of first spacers 120 above a top surface 138 of the remaining bottom portion 134 of the dummy gate structures, in accordance with one or more aspects of the present invention. Removal of the top portion of the first spacers may be accomplished, for example, with a selective wet etch, i.e., a wet etchant reactive to the first spacer material, but significantly less reactive to the second spacer material 124 or the isolation material 128.

FIG. 6 depicts the structure of FIG. 4 after removal of a portion of the first spacers above the bottom portion 134 of the dummy gate structures using, for example, a dry etch (e.g., plasma RIE), resulting in a top contact area 140 that is larger as compared to FIG. 4, but less than area 142 of FIG. 5, in accordance with one or more aspects of the present invention.

In one example, removal of part of the top portion (136, FIG. 4) of the first spacers 120 may result in a remaining top portion 144 of the first spacers having a tapered profile.

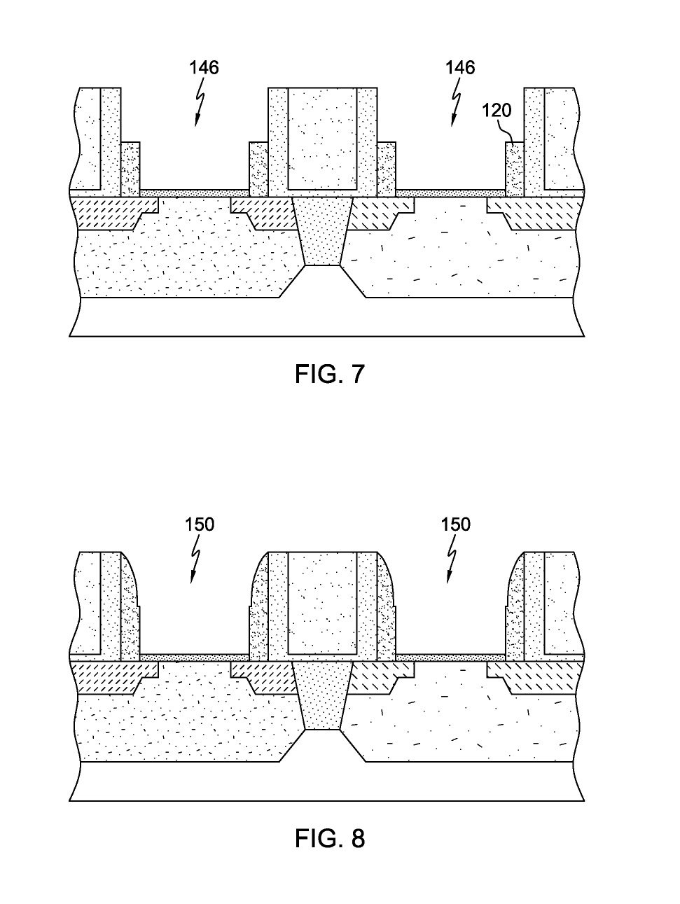

FIG. 7 depicts the structure of FIG. 5 after removal of the bottom portion (134, FIG. 5) of the dummy gate structures, resulting in gate openings 146, in accordance with one or more aspects of the present invention. In one example, removal of the bottom portion of the gate structure may be accomplished with a wet etch.

FIG. 8 depicts the structure of FIG. 6 after removal of the bottom portion (134, FIG. 6) of the dummy gates, resulting in gate openings 150 and exposing the bottom portion of the first spacers, in accordance with one or more aspects of the present invention.

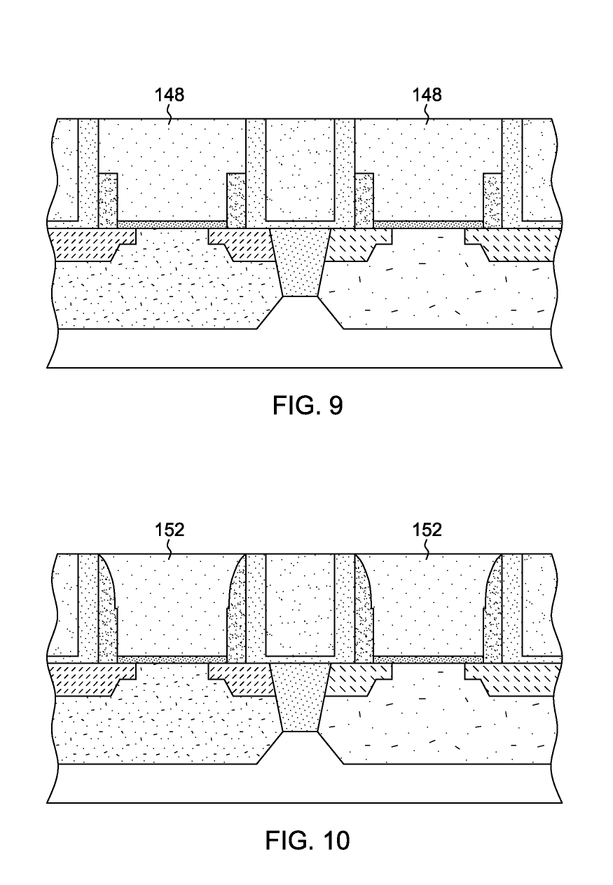

FIG. 9 depicts the structure of FIG. 7 after filling the gate openings (146, FIG. 7) with gate dielectric and gate conductive material (collectively, 148), the gates having a top portion that is wider than the bottom portion of the gate, in accordance with one or more aspects of the present invention.

FIG. 10 depicts the structure of FIG. 8 after filling the gate openings (150, FIG. 8) with gate dielectric and gate conductive material (collectively, 152), the gates having a top portion that is wider than the bottom portion of the gate, the top portions of the first or inner spacers having a tapered profile, in accordance with one or more aspects of the present invention.

The filling of gate openings in both FIGS. 9 and 10 may be accomplished in a conventional manner, and may include creation of various layers of, for example, high-k gate dielectric, work function material, and gate electrode metal layers. In one example, the gate electrode conductive material includes aluminum or tungsten.

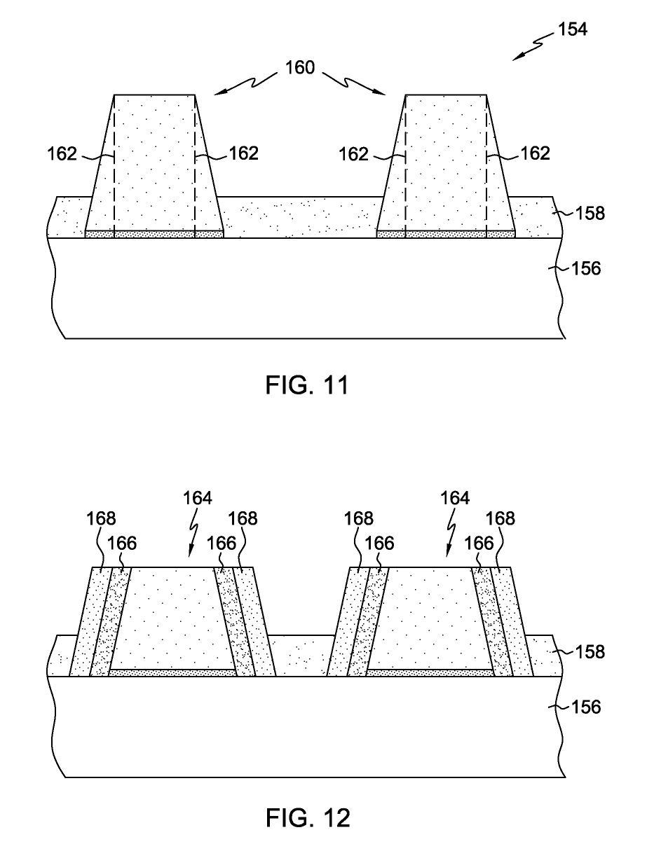

FIG. 11 depicts one example of a simplified, non-planar version 154 of the structure 100 of FIG. 2, including a semiconductor substrate 156, one or more raised structures coupled to the substrate (e.g., raised structure 158) and dummy gate structures 160 having a bottom portion being wider than the top portion of the gate structure, providing, in this example, a tapered sidewall profile, in accordance with one or more aspects of the present invention.

In one example, the raised structures may take the form of a “fin.” The raised structure(s) may be etched from a bulk substrate, and may include, for example, any of the materials listed above with respect to the substrate of FIG. 1. Further, some or all of the raised structure(s) may include added impurities (e.g., by doping), making them n-type or p-type.

Alternatively, a wide-top gate, explained in detail below, may be fabricated, in which case the gate sidewall profile would be vertical (indicated by the dashed lines 162). The dummy gate structures may be created, for example, by etching the dummy gate material. In one example, the dummy gate material may include polycrystalline silicon, and the etch may be accomplished, for example, by patterning via lithographic means, including the use of a lithographic blocking material, for example, photoresist, and removal thereof after patterning.

FIG. 12 depicts one example of the non-planar structure of FIG. 11 after replacing the dummy gate structures (160, FIG. 11) with final gate structures 164, including creation of first spacers 166 immediately adjacent the gate structures, creation of second spacers 168 immediately adjacent the first spacers, removal of the dummy gate material to create gate openings, and filling the gate openings with gate dielectric and gate conducting material (collectively, 170), in accordance with one or more aspects of the present invention.

The example of FIG. 12 assumes that wide-top gates (discussed in detail below) are co-fabricated with the wide-bottom gates. Two sets of spacers are needed for the wide-top gates, since the spacer pair closest to the gate will be partially removed. If the wide-bottom gate was not co-fabricated, then the two sets of spacers would not be needed; a single set of spacers would suffice, since there is no partial spacer removal for the wide-bottom gate.

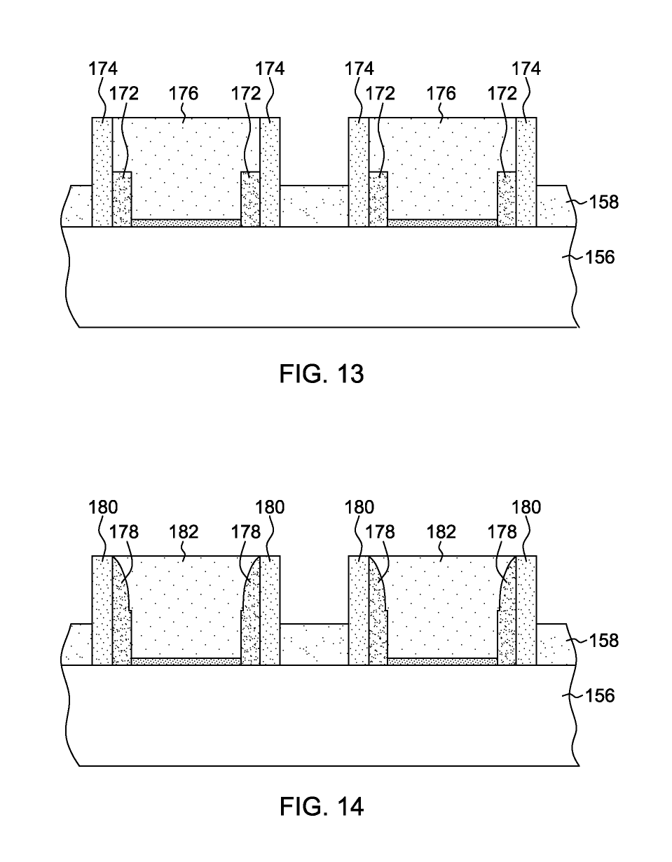

FIG. 13 depicts one example of the non-planar structure of FIG. 11 (vertical gate sidewall 162 version), a non-planar version of FIG. 9, after creation of first spacers 172 immediately adjacent the gate structures, creation of second spacers 174 immediately adjacent the first spacers, removal of the dummy gate material to create a gate opening, removal of a top portion of the first spacers and filling the gate opening with gate dielectric and gate conducting material (collectively, 176), in accordance with one or more aspects of the present invention.

FIG. 14 depicts one example of the non-planar structure of FIG. 11 (vertical gate sidewall 162 version), a non-planar version of FIG. 10, after creation of first spacers 178 immediately adjacent the gate structures, creation of second spacers 180 immediately adjacent the first spacers, removal of the dummy gate material to create a gate opening, removal of a tapered portion of a top part of the first spacers, and filling the gate opening with gate dielectric and gate conducting material (collectively, 182), in accordance with one or more aspects of the present invention.

In a first aspect, disclosed above is a method of fabricating a semiconductor structure. The method includes providing a starting semiconductor structure, the structure including a semiconductor substrate and a layer of dummy gate material over the substrate. The method further includes etching the layer of dummy gate material to create dummy gate(s) allowing for a subsequent replacement gate that has one of a top portion and a bottom portion thereof that is wider than the other of the top portion and the bottom portion.

Etching the layer of dummy gate material of the first aspect may include, for example, etching the layer of dummy gate material such that a bottom portion of the dummy gate(s) is wider than a top portion thereof. In one example, the dummy gate(s) may have, for example, a tapered side profile.

In another example, etching the layer of dummy gate material of the method of the first aspect may include, for example, etching the layer of dummy gate material to create dummy gate(s) having a top portion equally wide as a bottom portion thereof, creating first spacers immediately adjacent the dummy gate(s), creating second spacers immediately adjacent the first spacers, removing the top portion of the dummy gate(s), exposing a top surface of the bottom portion of the dummy gate(s), and removing a portion of the first spacers above the top surface. In one example, removing a portion of the first spacers may include, for example, removing all of the first spacers above the top surface. In another example, removing a portion of the first spacers may include, for example, tapering the first spacers above the top surface.

In one example, the starting semiconductor structure of the method of the first aspect may further include, for example, raised semiconductor structure(s) coupled to the substrate, the layer of dummy gate material surrounding the raised semiconductor structure(s), and the dummy gate(s) surrounding a portion of the raised structure(s).

Where raised structure(s) are present, the etching may include, for example, etching the layer of dummy gate material such that a bottom portion of the dummy gate(s) is wider than a top portion thereof, the dummy gate(s) having, for example, a tapered side profile.

In another example, where raised structures are present, the etching may include, for example, etching the layer of dummy gate material to create dummy gate(s) having a top portion equally wide as a bottom portion thereof, creating first spacers immediately adjacent the dummy gate(s), creating second spacers immediately adjacent the first spacers, removing the top portion of the dummy gate(s), exposing a top surface of the bottom portion of the dummy gate(s), and removing a portion of the first spacers above the top surface.

In a second aspect, disclosed above is a semiconductor structure. The structure includes, for example, a semiconductor substrate, source region(s), drain region(s) associated with the source region(s), and gate(s) associated with the source region(s) and the drain region(s), the gate(s) having a top portion and a bottom portion. One of the top portion and the bottom portion is wider than the other of the top portion and the bottom portion.

In one example, the top portion of the gate(s) is wider than the bottom portion thereof. Where the top portion of the gate(s) is wider than the bottom portion, the structure may further include, for example, first spacers immediately adjacent the gate(s), and second spacers immediately adjacent the first spacers.

In one example, where the spacers are present, a portion of the first spacers may be removed. In one example, the portion of the first spacers removed includes all of a top portion of the first spacers. In another example, the portion of the first spacers removed includes a tapered portion of a top portion of the first spacers.

In one example, the bottom portion of the gate(s) in the semiconductor structure of the second aspect is wider than the top portion thereof, the gate(s) having, for example, a tapered side profile.

The structure of the second aspect may include, for example, a first source(s) and a second source(s), a first drain(s) associated with the first source(s) and a second drain(s) associated with the second source(s), a first gate(s) associated with the first source(s) and the first drain(s) and a second gate(s) associated with the second source(s) and the second drain(s), a top portion of the first gate(s) being wider than a bottom portion thereof, and a bottom portion of the second gate(s) being wider than a top portion thereof.

In other words, the structure of the second aspect may include both wide-top and wide-bottom gates. In one example, where both wide-top and wide-bottom gates are present, the first gate(s) may be part of a logic device, and the second gate(s) may be part of a memory device.

In one example, the semiconductor structure of the second aspect may further include, for example, raised semiconductor structure(s) coupled to the substrate, the source region(s) and the drain region(s) may be situated at a top surface of the raised structure(s), the layer of dummy gate material surrounding the raised semiconductor structure(s), and the dummy gate(s) surrounding a portion of the raised structure(s) between the source region(s) and the drain region(s).

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting semiconductor structure, the structure comprising a semiconductor substrate and a layer of dummy gate material over the substrate; and
etching the layer of dummy gate material to create at least one dummy gate such that a subsequent replacement gate has one of a top portion and a bottom portion thereof that is wider than the other of the top portion and the bottom portion.

2. The method of claim 1, wherein the etching comprises etching the layer of dummy gate material such that a bottom portion of the at least one dummy gate is wider than a top portion thereof.

3. The method of claim 2, wherein the at least one dummy gate has a tapered side profile.

4. The method of claim 1, wherein the etching comprises:
etching the layer of dummy gate material to create at least one dummy gate having a top portion equally wide as a bottom portion thereof;
creating first spacers immediately adjacent the at least one dummy gate;
creating second spacers immediately adjacent the first spacers;
removing the top portion of the at least one dummy gate, exposing a top surface of the bottom portion of the at least one dummy gate; and
removing a portion of the first spacers above the top surface.

5. The method of claim 4, wherein removing a portion of the first spacers comprises removing all of the first spacers above the top surface.

6. The method of claim 4, wherein removing a portion of the first spacers comprises tapering the first spacers above the top surface.

7. The method of claim 1, wherein the starting semiconductor structure further comprises at least one raised semiconductor structure coupled to the substrate, wherein the layer of dummy gate material surrounds the at least one raised semiconductor structure, and wherein the at least one dummy gate surrounds a portion of the at least one raised structure.

8. The method of claim 7, wherein the etching comprises etching the layer of dummy gate material such that a bottom portion of the at least one dummy gate is wider than a top portion thereof, and wherein the at least one dummy gate has a tapered profile.

9. The method of claim 7, wherein the etching comprises:
etching the layer of dummy gate material to create at least one dummy gate having a top portion equally wide as a bottom portion thereof;
creating first spacers immediately adjacent the at least one dummy gate;
creating second spacers immediately adjacent the first spacers;
removing the top portion of the at least one dummy gate, exposing a top surface of the bottom portion of the at least one dummy gate; and
removing a portion of the first spacers above the top surface.

10. A semiconductor structure, comprising:
a semiconductor substrate;
at least one source region;
at least one drain region associated with the at least one source region; and
at least one gate associated with the at least one source region and the at least one drain region and having a top portion and a bottom portion, wherein one of the top portion and the bottom portion is wider than the other of the top portion and the bottom portion.

11. The semiconductor structure of claim 10, wherein the top portion of the at least one gate is wider than the bottom portion thereof.

12. The semiconductor structure of claim 11, further comprising:
first spacers immediately adjacent the at least one gate; and
second spacers immediately adjacent the first spacers.

13. The semiconductor structure of claim 12, wherein a portion of the first spacers are removed.

14. The semiconductor structure of claim 13, wherein the portion of the first spacers removed comprises all of a top portion of the first spacers.

15. The semiconductor structure of claim 13, wherein the portion of the first spacers removed comprises a tapered portion of a top portion of the first spacers.

16. The semiconductor structure of claim 10, wherein the bottom portion of the at least one gate is wider than the top portion thereof.

17. The semiconductor structure of claim 16, wherein the at least one gate has a tapered side profile.

18. The semiconductor structure of claim 10, wherein the at least one source comprises at least one first source and at least one second source, wherein the at least one drain comprises at least one first drain associated with the at least one first source and at least one second drain associated with the at least one second source, wherein the at least one gate comprises at least one first gate associated with the at least one first source and the at least one first drain and at least one second gate associated with the at least one second source and the at least one second drain, wherein a top portion of the at least one first gate is wider than a bottom portion thereof, and wherein a bottom portion of the at least one second gate is wider than a top portion thereof.

19. The semiconductor structure of claim 18, wherein the at least one first gate is part of a logic device, and wherein the at least one second gate is part of a memory device.

20. The semiconductor structure of claim 10, further comprising at least one raised semiconductor structure coupled to the substrate, wherein the at least one source region and the at least one drain region are situated at a top surface of the at least one raised structure, wherein the layer of dummy gate material surrounds the at least one raised semiconductor structure, and wherein the at least one dummy gate surrounds a portion of the at least one raised structure between the at least one source region and the at least one drain region.
